(19) United States
(12) Patent Application Publication
(10) Pub. No.: US 2022/0154448 A1
(43) Pub. Date: May 19, 2022

(54) CENTRALIZED CORE AND NODE SYSTEM FOR CONSTRUCTION PROJECTS

(71) Applicant: IP FACTORS, LLC, Los Angeles, CA (US)

(72) Inventor: Farhad Vafaee, Los Angeles, CA (US)

(21) Appl. No.: 17/527,686

(22) Filed: Nov. 16, 2021

Related U.S. Application Data
(60) Provisional application No. 63/114,323, filed on Nov. 16, 2020.
(60) Provisional application No. 63/114,341, filed on Nov. 16, 2020.
(60) Provisional application No. 63/114,349, filed on Nov. 16, 2020.
(60) Provisional application No. 63/114,390, filed on Nov. 16, 2020.
(60) Provisional application No. 63/114,401, filed on Nov. 16, 2020.
(60) Provisional application No. 63/114,408, filed on Nov. 16, 2020.
(60) Provisional application No. 63/114,417, filed on Nov. 16, 2020.
(60) Provisional application No. 63/114,426, filed on Nov. 16, 2020.
(60) Provisional application No. 63/114,452, filed on Nov. 16, 2020.
(60) Provisional application No. 63/114,460, filed on Nov. 16, 2020.
(60) Provisional application No. 63/114,468, filed on Nov. 16, 2020.
(60) Provisional application No. 63/114,472, filed on Nov. 16, 2020.
(60) Provisional application No. 63/114,476, filed on Nov. 16, 2020.
(60) Provisional application No. 63/114,485, filed on Nov. 16, 2020.
(60) Provisional application No. 63/114,489, filed on Nov. 16, 2020.
(60) Provisional application No. 63/114,492, filed on Nov. 16, 2020.
(60) Provisional application No. 63/115,497, filed on Nov. 18, 2020.
(60) Provisional application No. 63/114,755, filed on Nov. 17, 2020.

(51) Int. Cl. E04B 1/348; E04B 2/56

(52) U.S. Cl. CPC E04B 1/34869; E04B 2/56

(57) ABSTRACT

A centralized core and node system for use in an integrated component-based construction projects includes a centralized core configured to be positioned on at least one external wall of a building project. The centralized core includes a core frame to support one or more resource distribution mechanisms and a core shell connected to the frame to at least partially enclose the one or more resource distribution mechanisms and form at least one part of the external wall of the building project. The centralized core and node system also includes at least one resource node. The at least one resource node includes a node frame and at least one resource connection point. The resource connection point including a node input for connection to the centralized core and a node output for distributing a resource to a desired location in the building project.

### CROSS-REFERENCE TO RELATED APPLICATIONS

This application claims the benefit of U.S. Provisional Application No. 63/114,323, filed on Nov. 16, 2020, U.S. Provisional Application No. 63/114,341, filed on Nov. 16, 2020, U.S. Provisional Application No. 63/114,349, filed on Nov. 16, 2020, U.S. Provisional Application No. 63/114,390, filed on Nov. 16, 2020, U.S. Provisional Application No. 63/114,401, filed on Nov. 16, 2020, U.S. Provisional Application No. 63/114,408, filed on Nov. 16, 2020, U.S. Provisional Application No. 63/114,417, filed on Nov. 16, 2020, U.S. Provisional Application No. 63/114,426, filed on Nov. 16, 2020, U.S. Provisional Application No. 63/114,452, filed on Nov. 16, 2020, U.S. Provisional Application No. 63/114,460, filed on Nov. 16, 2020, U.S. Provisional Application No. 63/114,468, filed on Nov. 16, 2020, U.S. Provisional Application No. 63/114,472, filed on Nov. 16, 2020, U.S. Provisional Application No. 63/114,476, filed on Nov. 16, 2020, U.S. Provisional Application No. 63/114,485, filed on Nov. 16, 2020, U.S. Provisional Application No. 63/114,489, filed on Nov. 16, 2020, U.S. Provisional Application No. 63/114,492, filed on Nov. 16, 2020, U.S. Provisional Application No. 63/115,497, filed on Nov. 18, 2020, and U.S. Provisional Application No. 63/114,755, filed on Nov. 17, 2020. The entire disclosures of each of the above applications are incorporated herein by reference.

### FIELD

The present disclosure relates to a centralized core and node system for construction projects. Such core and node systems can be used for example in the context of Integrated Component-Based Construction (ICBC) methods.

### BACKGROUND

This section provides background information related to the present disclosure which is not necessarily prior art.

Traditional construction methods and related systems often include the preparation of a design and then the use of general contractors and/or skilled trades people to build the construction project based on the design. The contractors and skilled trades people often possess industry and trade knowledge and skills that enable such individuals to perform the necessary steps to complete the construction project efficiently and adequately to meet various requirements for the project such as price, timing, function, zoning, safety, durability and the like. The building materials used during construction projects using such traditional methods and systems often are sourced from a variety of vendors, suppliers and manufacturers that may have purchasing programs or relationships with the traditional contractors and/or trades people.

These traditional construction methods and systems, however, suffer from problems and drawbacks. For example, such traditional construction methods and systems require the individualized and/or specialized knowledge of the contractors and/or skilled tradespeople. Without such individuals, such as during labor shortages, increases in building demand or in geographic areas without such individuals, construction projects can be difficult to complete. Furthermore, when the availability of individuals with sufficient knowledge and skill is low, the quality, price, durability and safety of construction projects can suffer. Still further, the availability, timing and delivery of construction building materials can be slow, costly and inefficient using traditional supply chains that use traditional building material suppliers, vendors and manufacturers.

In other existing construction methods and systems, pre-fabricated construction projects can allow for all or portions of a construction project to be performed remote from a construction site. Such pre-fabricated construction projects or portions thereof can then be transported from the building location to the construction site. Such pre-fabricated construction methods and systems also suffer from problems and drawbacks. For example, existing pre-fabricated construction methods and systems often allow only for minor variation between construction projects such that the construction projects lack differentiation, personalization and/or the like. Another drawback is that there are limitations on what size, shape, weight and/or configuration can be transported from a building location to a construction site.

Therefore, there exists a need for improved construction methods and systems that address the problems and drawbacks of existing processes.

### SUMMARY

This section provides a general summary of the disclosure, and is not a comprehensive disclosure of its full scope or all of its features.

In some embodiments in accordance with the present disclosure, a centralized core and node system for use in an integrated component-based construction projects may include a centralized core configured to be positioned on at least one external wall of a building project. The centralized core may include a core frame to support one or more resource distribution mechanisms and a core shell connected to the frame to at least partially enclose the one or more resource distribution mechanisms and form at least one part of the external wall of the building project. The system may also include at least one resource node with a node frame and at least one resource connection point. The resource connection point may include a node input for connection to the centralized core and a node output for distributing a resource to a desired location in the building project.

In one aspect, the centralized core may include the one or more resource distribution mechanisms connected to the core frame.

In another aspect, the one or more resource distribution mechanisms may include an electrical distribution panel.

In another aspect, the one or more resource distribution mechanisms may include a forced air heating and cooling assembly.

In another aspect, the one or more resource distribution mechanisms may include a water distribution assembly.

In another aspect, the one or more resource distribution mechanisms may include a sewer assembly.

In another aspect, the core may include one or more core inputs that are connected to the one or more resource distribution mechanisms. The one or more core inputs maybe positioned externally to the shell and configured to connect an external resource to the one or more resource distribution mechanisms.

In another aspect, the centralized core may include an access door mounted to the frame to allow access from an external location outside the building project.

In another aspect, the centralized core may include a resource node positioned in a side of the frame other than the side that form at least one part of the external wall of the building project.

In another aspect, the core shell may include a roof portion wherein the roof portion forms a part of a roof of the building project.

In another aspect, the node frame may include a plurality of support members forming a wall section having a predetermined size.

In another aspect, the centralized core and the at least one resource node are pre-fabricated and delivered to a building site during different stages of the integrated component-based construction project.

In another aspect, the node frame may form a wall section having a predetermined size and the at least one resource connection point is configured for connection to a sink to supply potable water and to remove waste water.

In another aspect, the node frame may form a wall section having a predetermined size and the at least one resource connection point is configured to connect a sewer line to a toilet.

In another aspect, the node frame may form a wall section having a predetermined size and the at least one resource connection point is configured for connection to a laundry appliance.

In another aspect, the node frame may form a wall section having a predetermined size and the at least one resource connection point is configured for connection to a water supply for a refrigerator.

In another aspect, the at least one resource node may include a plurality of resource nodes positioned at predetermined locations in the building project.

In some embodiments in accordance with the present disclosure, a method of integrated component-based construction may include fixing a pre-fabricated core to a foundation of a building project. The pre-fabricated core may include an outer shell that forms at least one part of an external wall of the building project. The method may also include installing at least one pre-fabricated wall section in the building project. The at least one pre-fabricated wall section includes a resource connection for delivering a resource to a predetermined location in the building project. The method may also include connecting at least one public resource to the pre-fabricated core and connecting the resource connection to the pre-fabricated core for delivery of the at least one public resource to the predetermined location in the building project.

In one aspect, the pre-fabricated core includes a second resource connection on a portion of the outer shell different than the at least one part of the external wall of the building project.

In another aspect, a pre-fabricated component includes a marking fixed on an external surface thereof that indicates a location at which the pre-fabricated core is to be fixed to the foundation.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is an illustration of a construction environment in which the core and node systems of the present disclosure can be used.

FIG. 2 is an illustration of an example centralized construction model in a semi-exploded view.

FIG. 3 is an illustration the centralized construction model of FIG. 2 showing further individual components.

FIG. 4 is an illustration of example building project constructed using the core and node systems of the present disclosure.

FIG. 5 is an illustration of an example construction plan using in connection with the systems and methods of the present disclosure.

FIG. 6 is an illustration of an example building project in an intermediate state of construction showing a centralized core of the present disclosure.

FIG. 7 is an illustration showing an example wall section used to construct a building project of the present disclosure.

FIG. 8 is an illustration of an example centralized core of the present disclosure.

FIG. 9 is an illustration of another example centralized core of the present disclosure.

FIG. 10 is an illustration of another view of the centralized core of FIG. 9.

FIG. 11 is a sectional view of the centralized core of FIG. 9.

FIG. 12 is an illustration of another example centralized core of the present disclosure.

FIG. 13 is a sectional view of the centralized core of FIG. 12.

FIG. 14 is an illustration of an example double sink resource node of the present disclosure.

FIG. 15 is an illustration of an example ice maker resource node of the present disclosure.

FIG. 16 is an illustration of an example kitchen sink resource node of the present disclosure.

FIG. 17 is an illustration of an example laundry resource node of the present disclosure.

FIG. 18 is an illustration of an example shower resource node of the present disclosure.

FIG. 19 is an illustration of an example sink resource node of the present disclosure.

FIG. 20 is an illustration of an example toilet resource node of the present disclosure.

FIG. 21 is an illustration of an example tub resource node of the present disclosure.

FIG. 22 is a flow chart of an example method of integrated component-based construction using the core and node systems of the present disclosure.

Corresponding reference numerals indicate corresponding parts throughout the several views of the drawings.

### DETAILED DESCRIPTION

Example embodiments will now be described more fully with reference to the accompanying drawings. For purposes of the description hereinafter, it is to be understood that the embodiments described below may assume alternative variations and embodiments. It is also to be understood that the specific articles, compositions, and/or processes described herein are exemplary and should not be considered as limiting. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. The terms “couple,” “coupled,” “operatively coupled,” “operatively connected,” and the like should be broadly understood to refer to connecting devices or components together either mechanically, electrically, wired, wirelessly, or otherwise, such that the connection allows the pertinent devices or components to operate (e.g., communicate) with each other as intended by virtue of that relationship.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

In the present disclosure the singular forms “a,” “an,” and “the” include the plural reference, and reference to a particular numerical value includes at least that particular value, unless the context clearly indicates otherwise. When values are expressed as approximations, by use of the antecedent “about,” it will be understood that the particular value forms another embodiment. As used herein, “about X” (where X is a numerical value) preferably refers to ±10% of the recited value, inclusive. For example, the phrase “about 8” preferably refers to a value of 7.2 to 8.8, inclusive. Where present, all ranges are inclusive and combinable. For example, when a range of “1 to 5” is recited, the recited range should be construed as including ranges “1 to 4”, “1 to 3”, “1-2”, “1-2 & 4-5”, “1-3 & 5”, “2-5”, and the like. In addition, when a list of alternatives is positively provided, such listing can be interpreted to mean that any of the alternatives may be excluded, e.g., by a negative limitation in the claims. For example, when a range of “1 to 5” is recited, the recited range may be construed as including situations whereby any of 1, 2, 3, 4, or 5 are negatively excluded; thus, a recitation of “1 to 5” may be construed as “1 and 3-5, but not 2”, or simply “wherein 2 is not included.” It is intended that any component, element, attribute, or step that is positively recited herein may be explicitly excluded in the claims, whether such components, elements, attributes, or steps are listed as alternatives or whether they are recited in isolation.

The centralized core, node systems and related methods of the present disclosure provide improved components and construction methods that are more efficient, require less specialized knowledge, and can be completed in less time using less resources than existing methods and systems. The methods and systems of the present disclosure may include a centralized core and a node system connected to the centralized core to provide the distribution of utilities to a building project.

In many existing or traditional building projects, the utilities that are provided to the building project can be connected through separate systems and are installed by different tradespeople that have specialized knowledge of a particular utility but may not have knowledge of a different utility. Example utilities that may be provided to a building project, such as a residential home, include water, electricity, gas, sewer, internet service, cable television, and the like. Still further, building projects can also include internal systems such as hot water supply, heating, ventilation and air conditioning (HVAC) that also have to be routed to the various rooms or living spaces in the building project. Traditional systems for such utilities and resources are typically installed as separate systems by separate tradespeople such as HVAC technicians, plumbers, electricians, and the like.

The centralized cores and node systems of the present disclosure combine many of these utilities and distribution systems into a bundled or combined system that requires less specialized knowledge and less time once the core and node components are delivered to a building site. The pre-fabricated core can be installed and then the utilities and resources can be connected throughout the building project using the pre-fabricated node components. A centralized construction model that includes all the information about the structure and construction of the building project can be used to create fabrication data for a fulfillment center to fabricate the core and node components remotely from the building site. The core and node components can then be delivered to the building site as dictated by a construction plan in order to be installed just-in-time to improve efficiency in the construction process. While the construction process is described with respect to a residential home for the sake of brevity, the system and methods of the present disclosure can be applied to other construction projects as well.

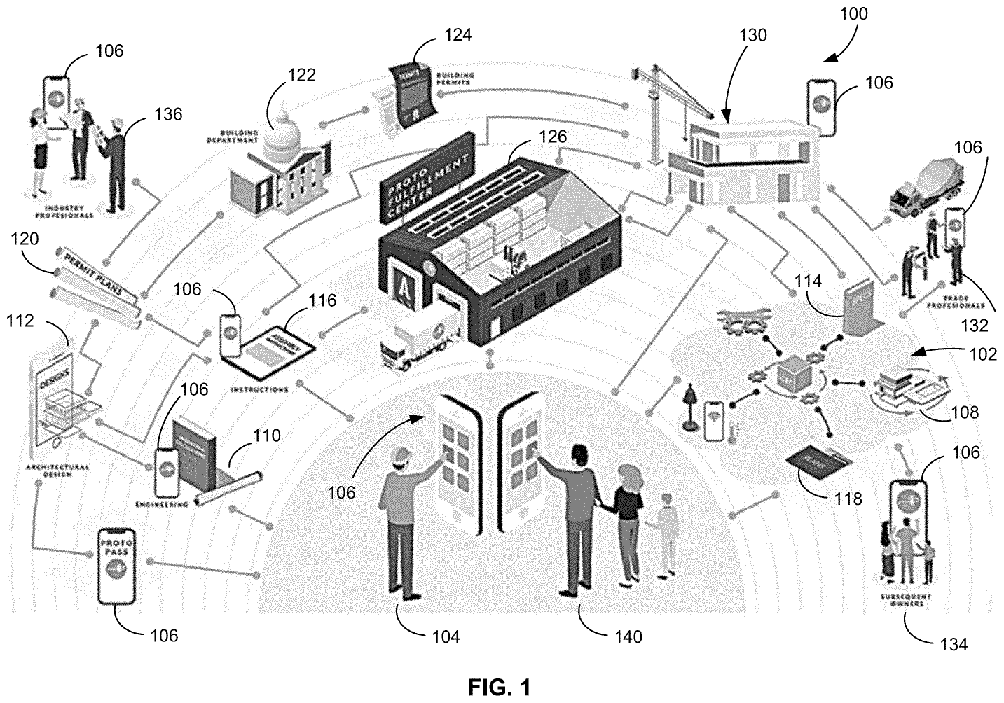

Referring now to FIG. 1, a construction environment 100 is shown. FIG. 1 illustrates an example environment 100 in which the centralized core and node system can be utilized. As shown, a user 140 or builder/contactor 104 can interact with a coordination platform 102 using a construction application 106. As indicated by the mobile phone icon, the various stakeholders in the environment 100 can also interact with the coordination platform 102 either directly or indirectly via a communication network, not shown. The coordination platform 102 can operate to share information and provide access to information during various stages of the construction process.

After a user (e.g., a contractor/builder or customer) engages with the construction system, the entire construction process can be managed and synchronized using the coordination platform 102. During the initial stages, the construction project can be designed and engineered by affiliate service providers 112, 110, respectively. The construction project design can be translated or embodied in a centralized 3D construction model 108 that can be stored in the coordination platform 102. The centralized 3D model 108 can be used to create all documentary information such as design specifications 114, drawings, renderings, etc. This documentation can then be used to create permit plans 120 and shared with other industry professionals 136 and submitted to regulatory authority 122 to obtain the permits 124 required to begin and/or execute the construction project.

The coordination platform 102 can also coordinate and determine a construction plan 118 that can include assembly instructions 116 and can group and allocate the building components and materials into stages, groups or “factors” for the construction of the construction project. As determined by the construction plan 118 and the determined factors, fabrication data, assembly data and/or factor data can be shared with fulfillment center 126 for the manufacturing, fabrication and delivery of the components and materials to the building site 130. Various trade professionals can use the delivered components and materials to complete the factors as scheduled and coordinated by the coordination platform 102. While all these actions are occurring the fulfillment centers 126 and the trade professionals can be interacting with the coordination platform 102 to provide updates on status and progress on completion of tasks. With this information, the coordination platform 102 can share and/or allow access to status information to users such as general contractors 104 and/or customers 140.

Once the construction project is complete, the coordination platform 102 can also serve as an information repository for construction, maintenance and repair information for the subsequent owners 134 of the construction project 130.

As can be seen, the construction systems of the present disclosure and aspects thereof, such as coordination platform 102 provide improvements in efficiency, information sharing, coordination of information and construction tasks over known systems and methods. Furthermore, the construction systems of the present disclosure can provide further added value by serving as information sources regarding the construction, maintenance and repair of construction projects that were built using the construction system(s). Construction systems such as those that can be used with the core and node system of the present disclosure are further detailed in U.S. patent application Ser. No. TBD, filed on Nov. 16, 2021 entitled SYSTEMS AND METHODS FOR INTEGRATED COMPONENT-BASED CONSTRUCTION, the entirety of which is hereby incorporated by reference.

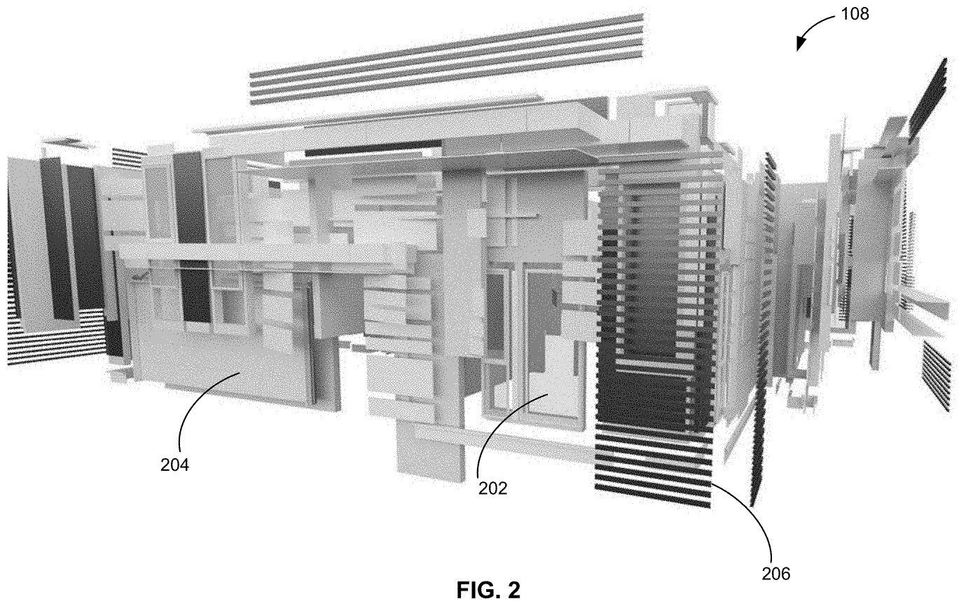

The coordination platform 102 can store and access information in the form of a centralized 3D construction model 108. The construction model 108 can be can be a 3D parametric model that includes each of the components and/or products that may be used to build the construction project 130. As shown in FIG. 2, the construction model 108 may allow a user to view and/or extract the information regarding the various components that are used to build the construction project. As shown in FIG. 2, the construction model 108 can be viewed in an exploded format that can separate the assembled project into the various components and products. A few examples of the components and products of the construction model 108 are shown in FIG. 2. As shown, the construction model 108 can include information regarding door 202, wall 204, cladding 206 and the like.

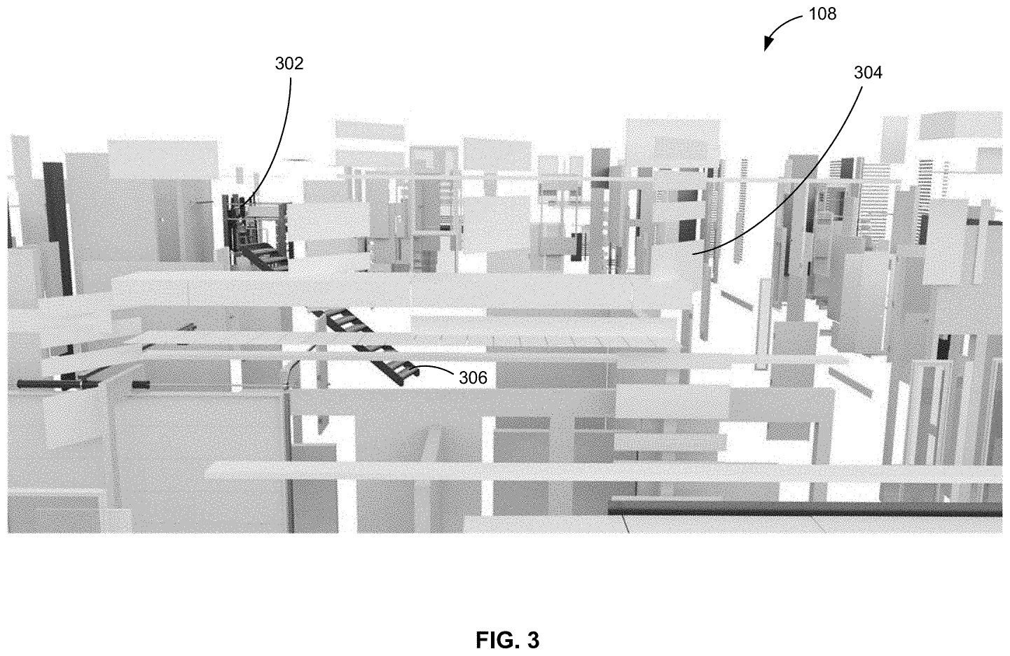

As shown in FIG. 3, the construction model 108 can be further separated and/or viewed in an exploded format to view not only the exterior components and/or products but also the interior components and/or products such as core 302, interior wall 304, staircase 306 and the like.

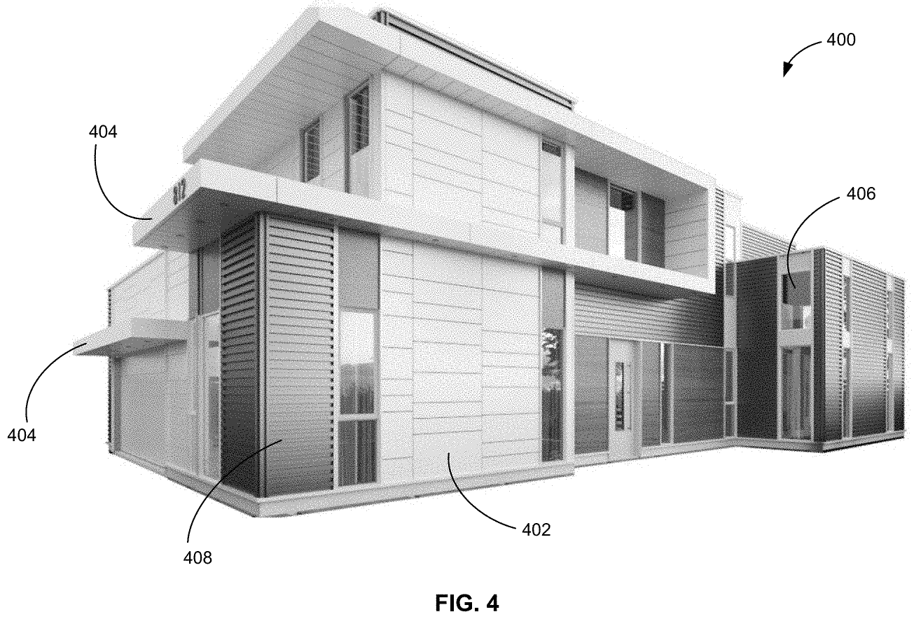

As shown in FIG. 4, an example construction project 400 can be a residential home. The construction project 400 can also be other types of construction projects such as commercial or public buildings or structures. In this example, the construction project 400 can be built using integrated component-based construction (ICBC) technology and components. Integrated component-based construction includes technology, methods and materials that may include a library of components and building processes that standardizes the fabrication and assembly of the construction project 400. Elements of ICBC technology can include standard components, non-standard components and common products.

Standard components can include building components that are proprietary components to the operator of the coordination platform 102. In one example, the standard components can include a library of standard components. The standard components do not change and are typically used in every construction project. There can be more than 100 standard components used on one example of the coordination system 100. Examples of standard components include coping, wall bases, doors, windows, corner trims, rebar matts. Standard components are typically used in the same manner for the same function in various building projects; thus could be inventoried.

Non-standard components are components that are principally the same but may have different design parameters such as different dimensions or different aspects specific to a particular construction project. Non standard components have a unique ID number. The non-standard components may be unique to a specific building project. Because of some of the dimensional characteristics, they often cannot be used in other circumstances. The non-standard components may have to be produced specifically for a building project. However, their family gives them the same consistent characteristics, only with certain dimensional differences. Examples of non-standard components include wall panels, Proto Core, Face Frames, cladding panels, stairs, sill plates, ledger boards, etc.

Common products are products that are commonly used building materials used in many constructions projects. These materials include fasteners, adhesives, sealers, windows and the like that are commonly used in construction projects.

Referring back to FIG. 4, the construction project 400 can include for example a plurality of standard components such as wall panel 402 and siding 408. The construction project 400 may also include non-standard components such as exterior extensions 404. As can be appreciated, the exterior extensions 404 can utilize common elements such as cross-sectional shapes, supports for extending the extensions away from the exterior of the construction project 400 and the like, but may have different lengths (i.e., distances along the exterior of the construction project 400). The construction project 400 can also include common products such as windows 406.

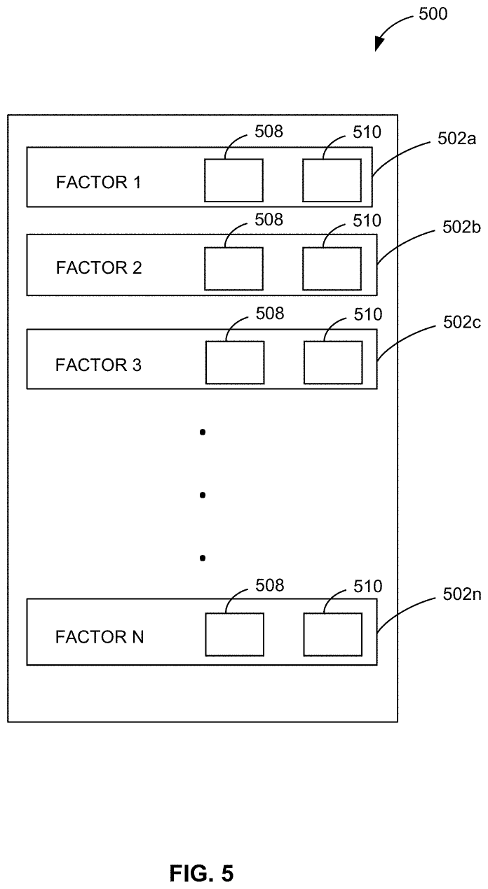

The coordination platform 102 can operate to prepare a construction plan 500. The construction plan 500 can be derived from the construction model 108. Construction plan 500 can include assembly instructions and can be separated into different stages or steps so that each stage of construction. A stage or step of construction can be termed a factor. As shown in FIG. 5, the construction plan 500 can include, in one example, a plurality of factors 502a, 502b, 502c . . . 502n. A factor 502 is a grouping of components, materials and tasks that are performed at a predetermined time during the completion of a construction project. The construction plan 500 can include any number of factors 502 that may be required for completion of a particular construction plan. Factors 502 can be understood to be a particular delineated step of the construction process. Example factors 502 can include for example, Project Kick-off, Footing, Slab, Core, 1st Floor Structure, 2nd Floor Structure, 3rd Floor Structure, Interior Walls and Ceiling, Roofing, Weatherproofing, Interior Doors, Electrical Boxes and Cans, Garage Door, Rough Plumbing, Rough HVAC, Fire Sprinklers, Wiring Electrical, Coping and Wall Base, Arch Projections, Exterior Trim, PVC Cladding, Exterior Painting, Metal Cladding, Accent Cladding, Insulation and Drywall, Tile Work, Interior Painting, Casework and Cabinets, Counter Top, Finish Mechanical, Electrical and Plumbing, Interior Finishes, Appliances, Finish Sprinkler Heads, and Close-out. In other examples, factors 502 can include other steps or stages of construction projects.

Each of the factors 502 above, can include multiple types of information. Each of the factors 502 may include, for example, fabrication information/data 508, and/or assembly information/data 510. The fabrication data 508 can include information that can allow suppliers and/or fulfillment centers to manufacture and/or acquire the materials that are required for a particular factor 502. The fabrication data 508 can include dimensions, materials, quantities, sizes, relationships between components and other information. The fabrication data 508 can also include marking data that indicates to the fulfillment centers and/or suppliers the markings that are to be included on the ICBC components. The assembly data 510 can include information for the construction professionals that describes how the components and products are to be assembled together at the construction site.

Each factor can include its own fabrication data 508 and assembly data 510. In this manner, the components and assembly information can be created and then delivered to the construction site for each factor 502 individually rather than entire loads or amounts of construction materials being shipped and/or delivered to a construction site. This type of step-by-step fabrication, delivery and assembly can simplify the construction process, reduce the likelihood of materials being wasted, stolen or being damaged. Once each factor is completed at the construction site, the next factor 502 can be initiated and then completed. Once all the factors 502 are completed, the construction project is complete.

As discussed above, the coordination platform 102 can determine the construction plan like the construction plan 500 previously described. The coordination platform can use the centralized construction model 108 to determine the various factors 502a to 502n that may be required for a particular construction project. The coordination platform 102 can extract the components for each stage of construction (i.e., each factor 502) and then group the components together for each factor. The use of Integrated Component-Based Construction Components and details thereof are further described in U.S. patent application Ser. No. TBD, filed on Nov. 16, 2021 entitled INTEGRATED COMPONENT-BASED CONSTRUCTION COMPONENTS AND RELATED METHODS, the entirety of which is hereby incorporated by reference.

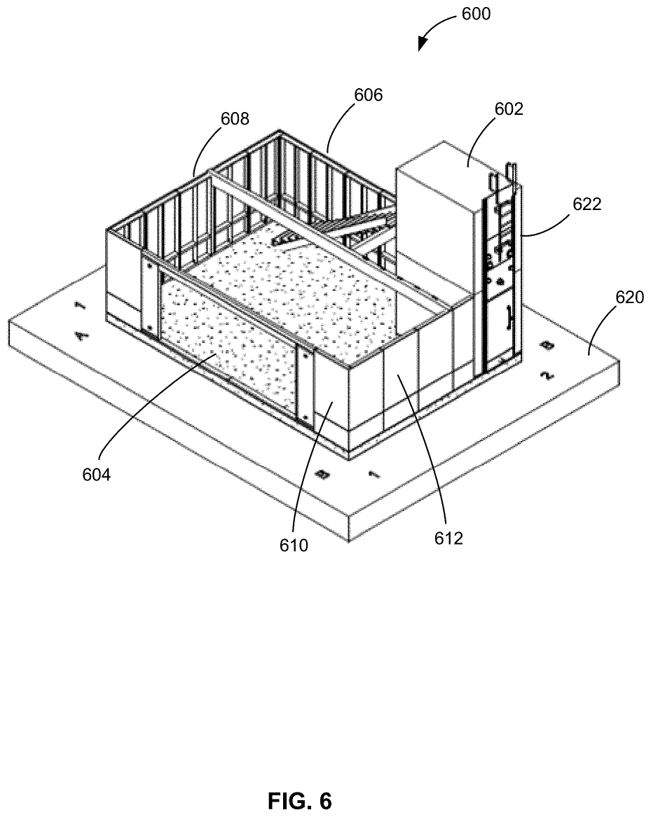

The core and node systems of the present disclosure can be installed in various factors during the construction process. Referring now to FIG. 6, an example building project 600 is shown. The building project 600 is shown in an intermediate stage of assembly. The building project 600, as shown, includes a centralized core 602, a first exterior wall 606, a second exterior wall 608, a third exterior wall 610, and a fourth exterior wall 612. The building project 600 is positioned on a foundation 604 that can be poured with concrete or formed using other suitable methods.

As will be further described, the core 602 can be pre-fabricated at a facility remote from the building site 620. After a user designs the building project 600, the centralized construction model 108 is determined that includes all the specifics and details that are necessary to build the project 600. One aspect that is created and defined by the centralized construction model 108 is the specifications of the centralized core 602. The centralized core is centralized in that it incorporates, in one assembly, all or most of the connections that the building project 600 will need to public and external resources such as water, sewer, electricity, gas, ventilation, internet service, phone service, cable television, and the like. The core 602 is centralized in that it is the one location in the building project 600 that the builder uses to connect to the external resources, to service the mechanical systems that supply or distribute such resources and to perform other maintenance requirements.

The centralized core 602 is physically positioned centrally in the building project 600 as can be seen in FIG. 6. The core 602 is positioned such that the shell 622 or outer housing of the core 602 forms a part of at least one of the exterior walls 606, 608, 610, 612. In the example building project 600 shown, the core is positioned at a corner of the building project 600. The shell 622 of the core 602 forms part of first exterior wall 606 and part of fourth exterior wall 612.

In one example method of assembly, a sill plate can be installed on the building site 620. The sill plate can include markings or label that is fixed to the external surface of the sill plate. The sill plate can indicate the location at which various components for the building project 600 should be installed. The sill plate can indicate where the core 602 should be placed on the foundation 604. The core 602 can be one of the first structures that is installed on the foundation 604 due to the size and weight of the core 602. A crane, forklift, EZ-jack or other support/lifting equipment can be used to lift and position the core 602 in the desired position on the foundation 604. Once in the predetermined position, as indicated by the centralized construction model 108, the core 602 can be secured into position on the foundation 604 using anchor bolts, hold downs or other suitable fasteners or connectors.

The exterior walls 606, 608, 610, 612 can then be assembled around the core 602 and be secured in predetermined locations. The construction process, as previously described, can continue factor by factor until the building project 600 is finished. During such a process, wall sections are assembled into the building project 600 as determined by the centralized building model 108.

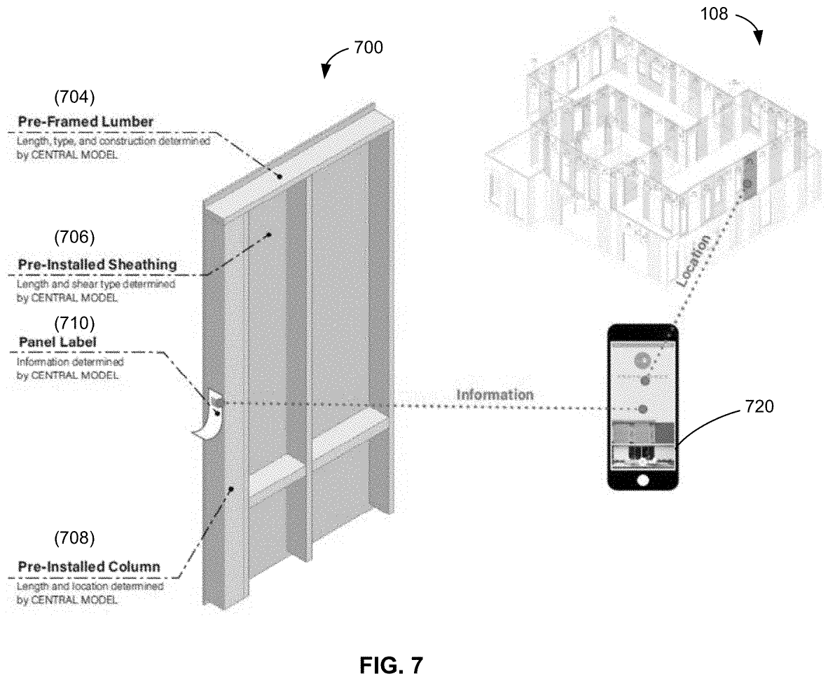

An example is shown in FIG. 7, the centralized model 108 can include the details for construction of multiple wall sections 700 that are connected together to form the building project. The builder at the building site 620 can access the centralized model 108 using a construction app on a mobile phone 720, for example. The wall section 700 can have various configurations and but is made of predetermined size such as in widths of two or four feet. In other examples, other predetermined sizes can be used. The example wall section 700 shown in FIG. 7 is made of a framed lumber frame 704, a column 708 and sheeting 706. The wall section 700 can be fabricated remote from the building site 620 and then simply secured in the desired location. The wall section 700 can include a label 710 that can include identifying information (such as a QR code) that the builder can use to identify the wall section 700 when it is delivered to the building site to determine its location in the building project.

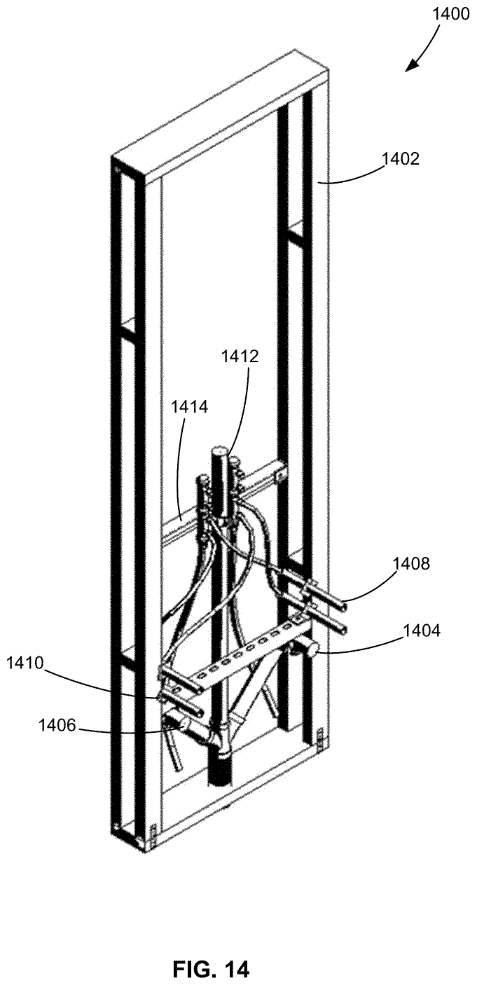

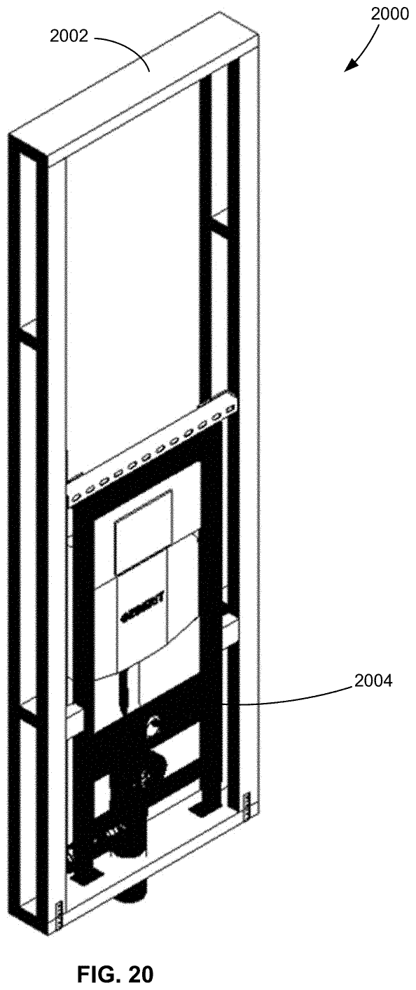

While the example wall section 700 is a relatively simple wall section in that it does not include any mechanical, electrical or plumbing (MEP) components, other wall sections can be configured as resource nodes for the core and node systems of the present disclosure. As will be further described, the wall section 700, in other examples (e.g., FIGS. 14-21), can include resource connection points that can connect fixtures or appliances in the building project to external resources. For example, the wall section can include connection points for supplies of potable water, sewer lines, electrical lines, and the like.

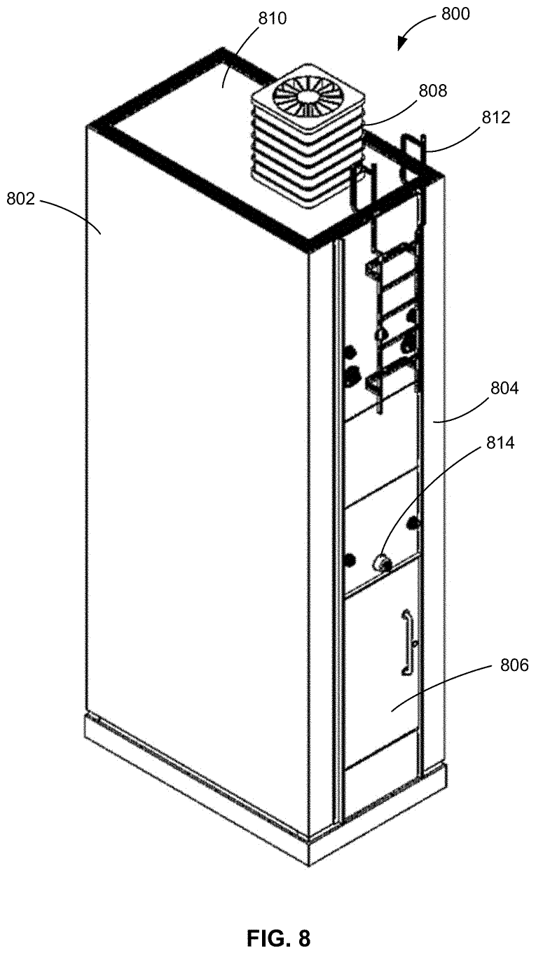

Referring now to FIG. 8, another example centralized core 800 is shown. In this example, the core 800 is two-stories in height. The core 800 includes an outer shell 802 that can be formed of a suitable sheathing material such as a composite or synthetic engineering siding, a PVC material, or the like. In other examples, other materials such as aluminum, or a wood-based siding can be used. The shell 802 can be fit with a door 806 that can be included in one of the sides 804 of the shell 802 that forms a part of an exterior wall of the building project. In this position, the door 806 can provide access to the interior of the core 800 from a location outside of the building project. Technicians, repair persons, builders and the like can easily access the contents of the core 800 without having to enter an interior of the building project.

As further shown, the exterior side 804 of the core 800 can also include one or more exhaust ports 814 and a ladder 812. The exhaust ports 814 can provide a pathway for exhaust gasses to exit the core 800. As will be further described, the core 800 can include various resource distribution mechanisms such as a furnace, hot water heater or the like. These types of mechanisms may require hazardous exhaust gases (e.g., carbon monoxide) to be vented to the exterior of the building project. The exhaust port 814 can provide such venting for the core 800. The ladder 812, in this example, can be attached to the external side 804 can provide access to the roof portion 810 of the core 800. The ladder 812 can allow workers to access components of the core 800 that may be located on the roof portion 810 such as condenser 808. Furthermore, the roof portion 810 of the core 800 can form part of the roof of the building project. The top of the core 800 can be substantially aligned with the roof of the building project. Thus, the ladder 812 can allow workers, homeowners, or others to access the roof of the building project in addition to the roof portion 810 of the core 800.

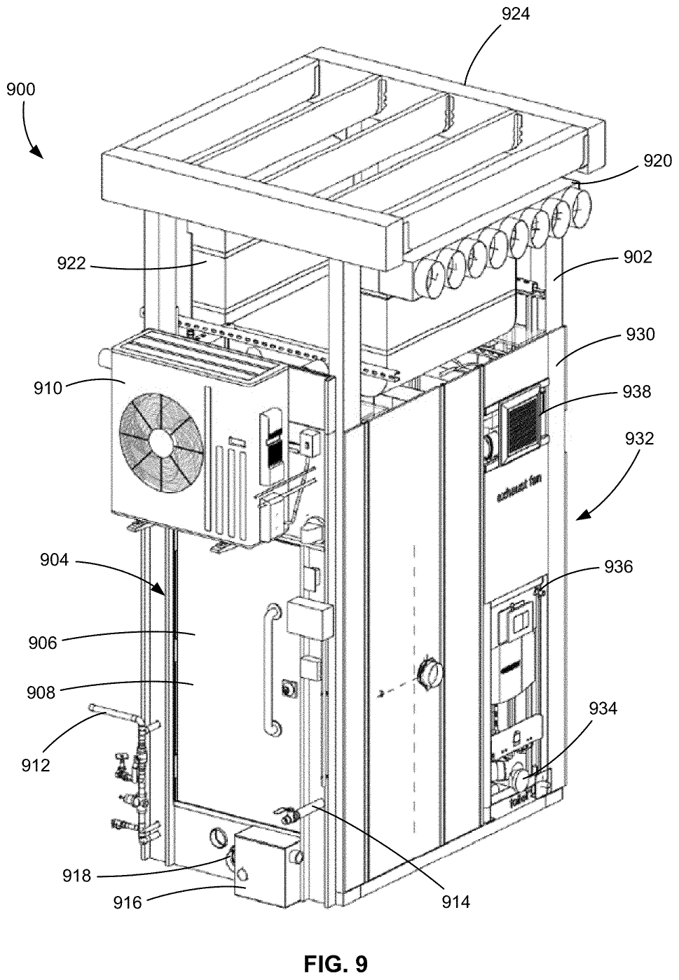

Referring now to FIG. 9, another example centralized core 900 is shown. In this example, the core 900 includes a frame 902 that includes one or more supports that create a support structure for the various elements of the core 900. The frame 902 can be formed using one or more lengths of lumber (e.g., two by fours) or other metal or composite framing members can be used. A shell 904 can be secured to the frame to enclose or at least partially enclose the elements of the core 900 located in the interior of the frame 902. The frame 902 and shell 904 can form a portion of an external wall of the building project. In this example, the side 906 can form part of an external wall of the building project and can include the door 908 to provide access to the interior of the core 900 as previously described.

In this example, the side 906 also includes a condenser 910 fit to the shell 904 and/or the frame 902. The condenser 910 can be any suitable condenser sized in accordance with the size of the building project. The condenser 910 can form part of the forced air heating and cooling system included in the core 900 to provide heating and/or air conditioning for the building project. As further shown, the external side 906 can also include one or more core inputs or outputs for various resources or utilities for the building project. In this example, a potable water input 912 is included as well as a natural gas input 914. The core 900 may also include an electrical service connection box 916 and a sewer connection 918. In other examples, other connections and/or inputs can also be included on the core. As can be appreciated, the positioning of the connections and/or inputs on the external side of the core 900 make the connection of the resources and utilities much easier than existing or traditional construction methods. The connections are standardized and come pre-fabricated as part of the core 900.

As further shown in this example, the core 900 includes an upper portion with air handling distribution plenums. An air supply plenum 920 is positioned on one side of the core 900 and an air return plenum 922 is positioned on an opposite side of the core 900. The distribution air ducts can be connected to the air supply plenum 920 and/or to the air return plenum 922 to distribute and capture air as part of the HVAC system for the building project. As further shown, a support structure 924 can be included on a top of the core 900. The support structure 924 can be formed with suitable framing members to form part of a roof support structure or be integrated with the joist support structure of the building project to form a floor for a second floor above the core 900.

The core 900 can also be configured to include a resource node in one the sides other than the side that forms the external wall of the building project. In the view shown in FIG. 9, the side 930 includes a resource node 932. A resource node is a location in the building project where a utility or other resource is provided for use to the inhabitants or users of the building project. For example, resource nodes can include connection points for potable water, connections for sewer, connections for electricity, communication and the like. The resource nodes are typically positioned at locations in the building structure so that fixtures can be attached to the resource nodes. Fixtures such as sinks, toilets, appliances (e.g., laundry machines, refrigerators), showers, tubs and the like can be attached to resource nodes.

The resource node 932 shown in FIG. 9, is a node that allows for the attachment of a toilet. The toilet can connect to a sewer connector 934 and includes a water connector 936. The resource node 932 also includes an exhaust fan 938 that can be used to ventilate air from the bathroom that will be installed adjacent to the resource node 932. As can be appreciated, the side 930 can form part of an interior wall of a bathroom when the building project is assembled around the core 900.

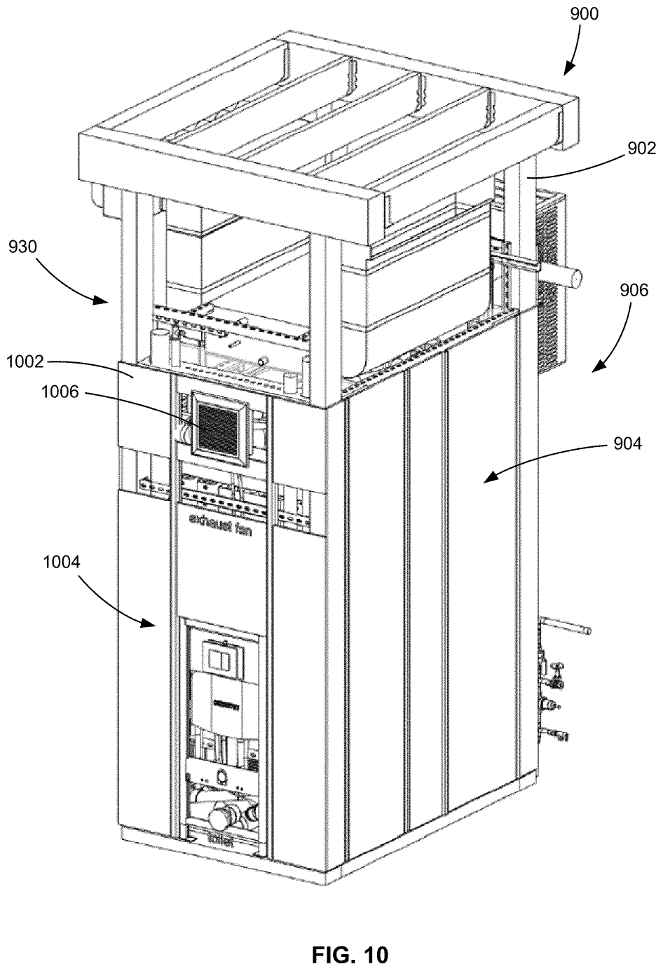

Referring now to FIG. 10, another view of the core 900 is shown. This example shows a view approximately 180 degrees from the view shown in FIG. 9. As can be seen, a side 1002 that is located opposite to the external side 906 includes a second resource node 1004. The second resource node 1004 is similar to the first resource node 932 previously described that is located on side 930 of the core 900. The second resource node 1004, in this example, is another location for connection of a second toilet. The second resource node 1004 also includes a second exhaust fan 1006. The second resource node 1004 can be positioned in the building project such the side 1002 forms at least part of a wall of a second bathroom (different from the bathroom that includes the first resource node 932).

In other examples, the first resource node 932 and the second resource node 1004 can include other types of connection points for the distribution or connection of other utilities or other public resources as will be described with respect to the various types of resource nodes contemplated by the present disclosure.

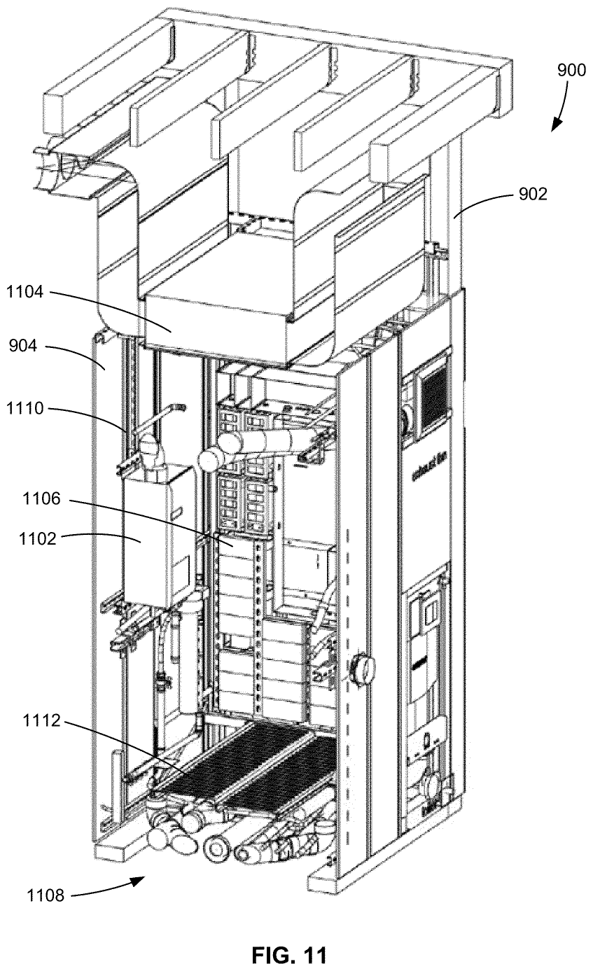

Referring now to FIG. 11, a sectional view of the core 900 is shown. The sectional view shown in FIG. 11 is at the same orientation shown in FIG. 9 but cut along a section plane substantially parallel with the exterior side 804. As can be seen, the shell 904 defines an interior space in which various elements are secured. The elements inside the interior space of the shell 904 can include one or more resource distribution mechanisms. In this example, the resource distribution mechanisms can include a hot water heater 1102, an air handling unit 1104, an electrical distribution panel 1106, a sewer manifold system 1108 and a water distribution manifold system (not shown). Further information regarding the electrical distribution panel and related electrical systems is described in U.S. patent application Ser. No. TBD, entitled INTEGRATED WHOLE HOUSE ELECTRICAL SYSTEMS filed on Nov. 16, 2021, the entirety of which is hereby incorporated by reference.

The core 900 can include an internal chassis 1110 that can be secured to the frame 902. The chassis 1110 can include a structure of u-channels or other support members that creates a grid for the attachment of the various resource distribution mechanisms and other elements in the core 900. The chassis 1110 can be formed from steel, aluminum channels or other support structures that allow for the simple attachment, removal and servicing of the elements of the core 900. The core 900 can also include a floor 1112 that is attached to the frame 902 and/or to the chassis 1110 to provide a surface that a technician, builder or other worker can stand on when working or servicing the core 900.

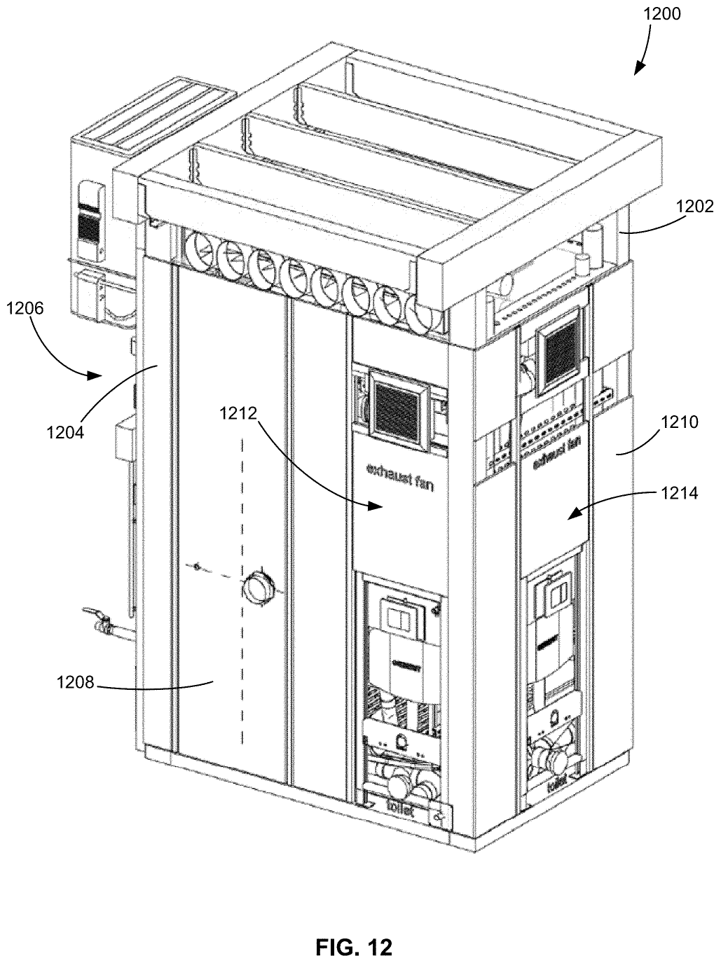

Another example core 1200 is shown in FIG. 12. The example core 1200 is similar to the core 900 previously described. As shown, the core 1200 includes a frame 1202 and a shell 1204 as previously described. This example core 1200 has a height that is less than a height of the core 900 and can be used for more compact building projects, for example. The core 1200 includes an exterior side 1206 that forms at least part of an exterior wall of the building project, a first side 1208 next to the exterior side 1206, and a second side opposite to the exterior side 1206. The core 1200 includes a first resource node 1212 positioned on the first side 1208 and a second resource node 1214 positioned on the second side 1210. The first resource node 1212 is configured as toilet connection point that can be located in a first bathroom in the building project. The second resource node 1214 is also configured as a toilet connection point and can be located in a second bathroom in the building project.

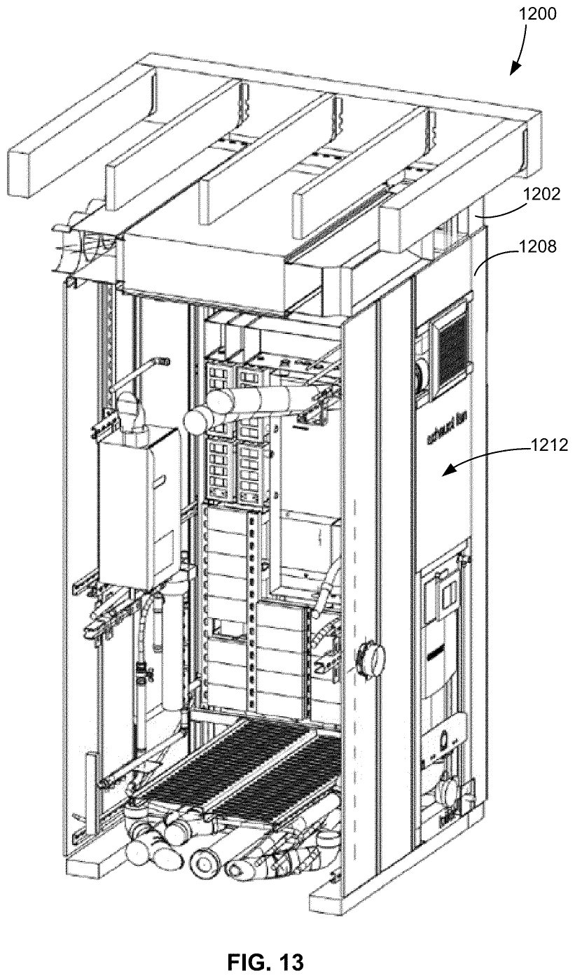

A sectional view of the core 1200 of FIG. 12 is shown in FIG. 13. Similarly, to the core 900 previously described, the shell 1204 defines an interior space in which various resource distribution mechanisms can be positioned. In this example, the various resource distribution mechanisms are similar that previously described and are repeated here for the sake of brevity.

Referring now to FIGS. 14-21 show example resource nodes that can be used in connection with the cores of the present disclosure. The cores are installed into the building project and then the various stages of construction are completed to build, for example, the exterior walls and then the interior walls of the building project. During such construction multiple wall section (such as the wall section 700 previously described) are assembled into predetermined locations as is shown and dictated by the centralized construction model. Some of the wall sections are resource node wall sections and various examples of these are shown in FIGS. 14-21. The wall sections with the resource nodes are installed into bathrooms, laundry rooms, kitchens, and other rooms that require fixtures such as sinks, tubs, showers, etc. or appliances such as refrigerators, laundry machines, etc. Each of the resource nodes are connected to the core by suitable wiring, piping, ductwork, etc. so that the resources from the core can be distributed to the resource nodes.

Referring now to FIG. 14, an example double sink resource node 1400 is shown. The resource node 1400 includes a wall section 1402 that can have the structure previously described as well as various resource connection points for the resources needed for a double sink. In this example, the resource node 1400 includes a first sewer connection 1404, a second sewer connector 1406, a first water connector 1408 and a second water connector 1410. As can be appreciated, the first water connector 1408 and the second water connector 1410 can each include a cold water source and a hot water source as typically provided in sink fixtures. The resource node 1400 can also include a vent 1412 for venting the sewer line. The resource connectors can be supported in the wall section 1402 by support members 1414. The resource node 1400 can be installed in a bathroom, for example, for which the design and centralized construction model calls for a double sink fixture. The resource node 1400 can arrive pre-fabricated in the manner shown at the building site. Thus, the builder need only to set the wall section in place and secure it to the adjacent components. While not shown, the resource node 1400 (or any of the resource nodes of the present disclosure) can include a marking a label that uniquely identifies the resource node 1400 and provides the necessary information to the builder to install the resource node in the proper location in the building project.

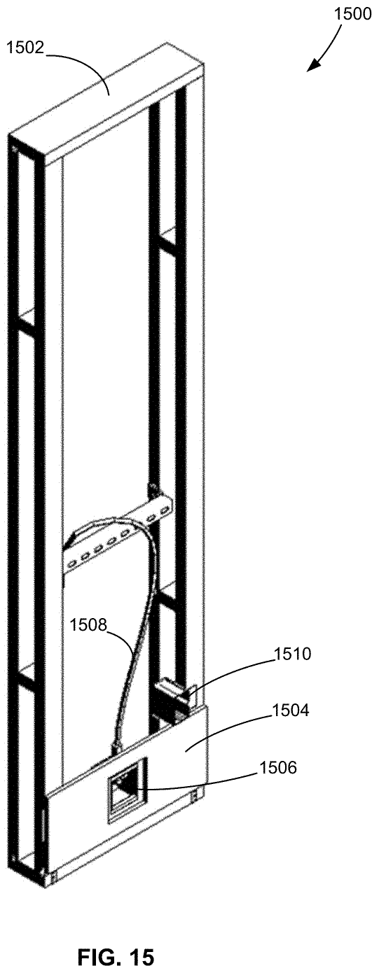

Another example resource node is shown in FIG. 15. The example resource node 1500 is an ice maker resource node. The resource node 1500 can be installed in a predetermined location in a kitchen, for example, at a position where a refrigerator will be positioned so that water can be supplied to the refrigerator for the ice maker. The resource node 1500 can include a wall section 1502. A panel 1504 can include a recessed water connection point 1506. A water line 1508 is coupled to the water connection point 1506 that will, in turn, be coupled to a potable water source in the centralized core. The resource node 1500 can also include an electrical box 1510 in which an electrical outlet can be positioned to provide power to the refrigerator. As can be seen, with the resource node 1500 arriving at the building site in a pre-fabricated manner, the on-site builders need only install the wall section 1502 at the predetermined location. Electricians or plumbers are not required to look at complicated drawings and make measurements to determine a placement for the outlet or for the water line. This significantly improves the efficiency of the construction process.

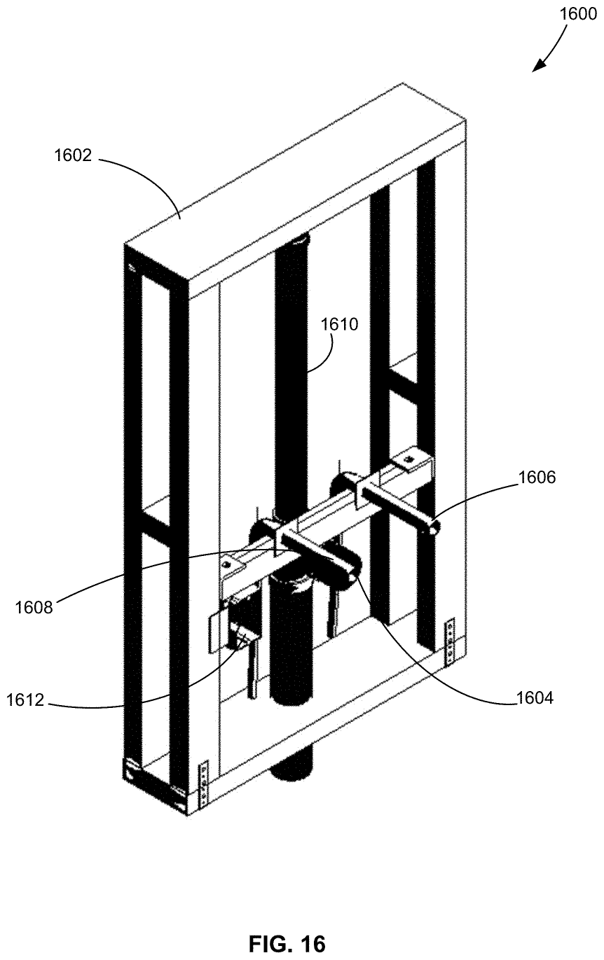

Referring now to FIG. 16, a kitchen sink resource node 1600 is shown. As can be seen, the resource node 1600, in this example, has a shorter overall height than previously shown resource nodes. This may be the case because a window will be placed above the kitchen sink that will be installed on the resource node 1600. In other examples, the wall section 1602 may have a taller height if no window will be installed.

The resource node 1600 can include a sewer connection 1604, a cold water connection 1606 and a hot water connection 1608. The node 1600 can also include a vent 1610 and an electrical box 1612. The connections are those typical for a kitchen sink with an electric garbage disposal. Once again, this pre-fabricated resource node 1600 is delivered to the building site as shown so that no drawings or measurements are required by the builder. The wall section 1602 is merely installed in the location and sequence as dictated by the centralized construction model.

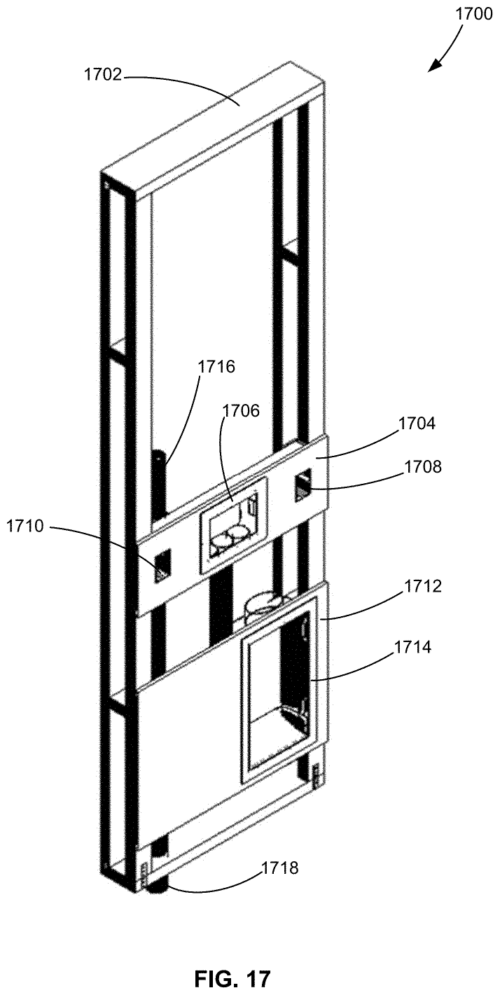

An example laundry resource node 1700 is shown in FIG. 17. In this example, the wall section 1702 will be positioned in a location at which a washing machine and/or a dryer will be located in the building structure. To support these appliances, the resource node 1700 can include an upper panel 1704 that includes a water/drain recess 1706, a first electrical box 1708 and a second electrical box 1710. The water/drain recess 1706 can include sources of hot and cold water as well as a sewer connection. As can be appreciated, the sewer connection can be coupled to the vent 1716 and the sewer drain 1718.

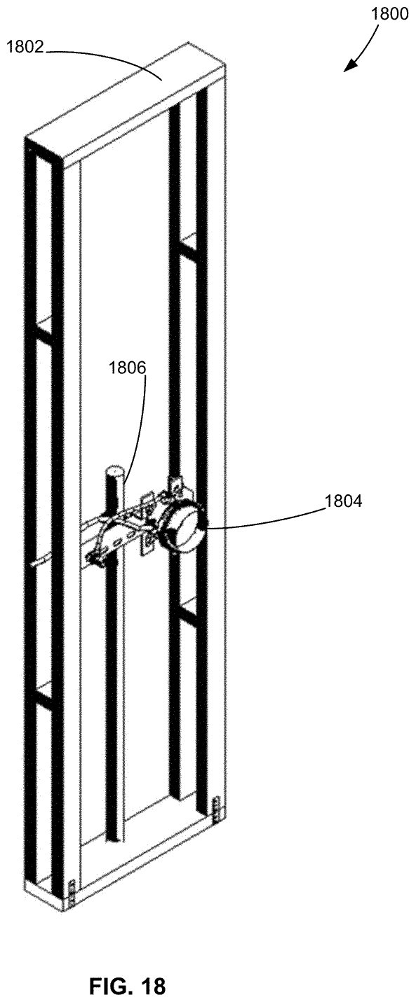

FIG. 18 illustrates an example resource node 1800 for use to connect resources to a shower. As shown, the resource node 1800 includes a wall section 1802 that may include a water connection point 1804 and a vent tube 1806. The water connection point 1804 can include lines for the supply of hot and cold water and can be used to connect to traditional shower fixtures such as adjustments knobs, dispensers and the like. The vent tube 1806 can be used to vent the drain of the shower. As like the other resource nodes, the resource node 1800 can be delivered to the building site in a pre-fabricated form such as that shown in FIG. 18.

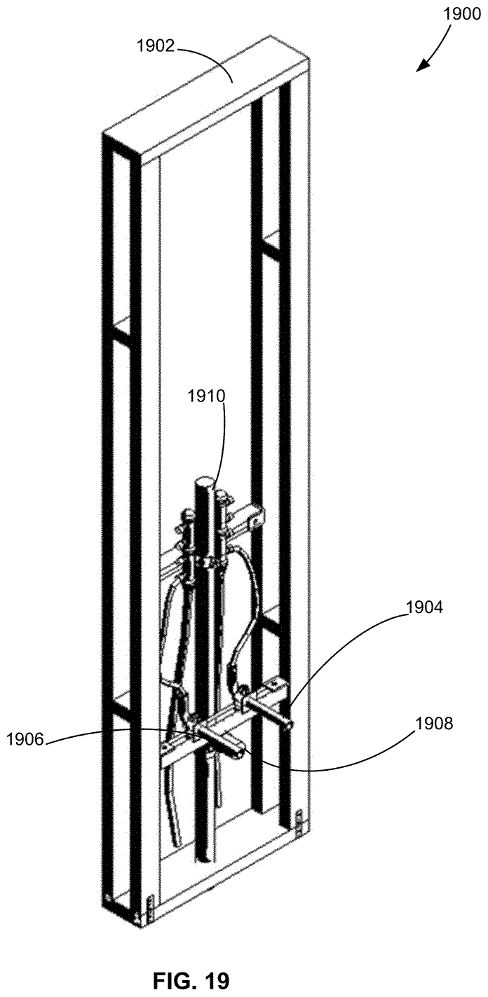

FIG. 19 shows an example resource node 1900 that can be used to connect a single vanity or sink. The resource node 1900 includes a wall section 1902 that can form a frame to hold a cold water connection 1904, a hot water connection 1906, a sewer connection 1908 and a vent 1910. The resource node 1900 is similar in many respects to the resource nodes previously described in that the resource node can be pre-fabricated and delivered to the building site as shown. A single vanity sink can be attached to the resource node 1900 in a bathroom that may be located in the building project.

In another example, a resource node 2000 can be configured for the attachment of a toilet. The resource node 2000 can be similar to the resource nodes discussed above that are included with the centralized core. The resource node 2000 in this example can include a wall section 2002 so that the resource node can be positioned remotely from the core. The resource node 2000 can include a toilet frame 2004 that can include a water and a sewer connection point. While not shown or visible, the resource node 2000 can also include a vent and an exhaust fan. The resource node 2000 can be pre-fabricated and delivered to the building site in an assembled form.

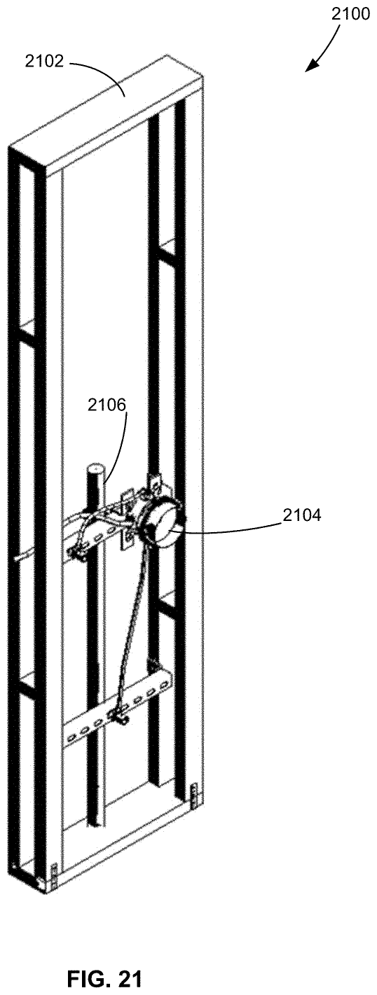

The resource node 2100 is another example. As shown in FIG. 21, the resource node 2100 can be configured to supply connections for a tub. The resource node 2100 can include a frame 2102, a water connection 2104 and a vent 2106. The water connection 2104 can supply hot and cold water for a tub faucet and the vent 2106 can be connected to a sewer connection for the tub. The resource node 2100 can be pre-fabricated and delivered to the building site in an assembled form.

While the above resource nodes describe various connections for fixtures and appliances, other resource nodes can also be used with the systems, cores, and methods of the present disclosure. As explained above, the resources nodes can be pre-fabricated and identified with a permanent marking or a label so that proper installation instructions and installation location can be determined by a builder at the building site. The builder can access the centralized construction model, for example, using a mobile phone or other computing device to obtain such installation instructions and/or installation location without the need to consult engineering or architectural drawings.

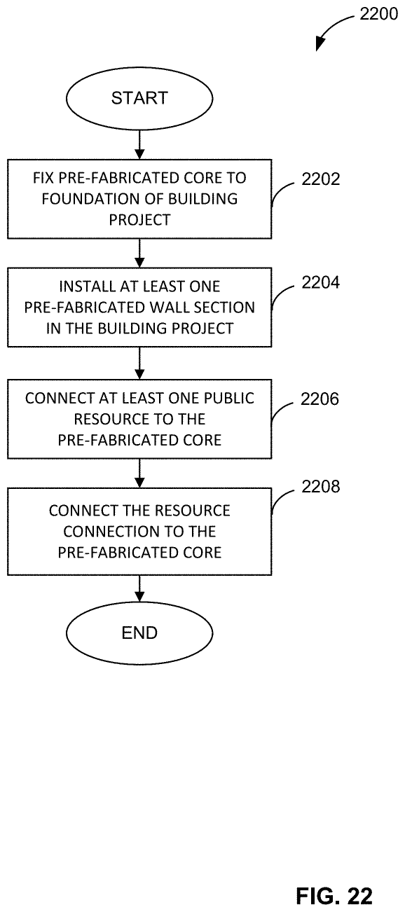

Referring now to FIG. 22, an example method 2200 is shown. The method 2200 provides a method for integrated component-based construction that utilizes the core and node systems of the present disclosure. The method begins at step 2202 in which a pre-fabricated core is fixed to a foundation of a building project. The pre-fabricated core can have the features and structure of any of the example cores previously described. The pre-fabricated core can include an outer shell that forms at least part of an external wall of the building project. The core can be fixed to the foundation using any suitable attachment method such as anchor bolts, hold downs or the like. In some examples, a sill with a label or other marking is used to define a layout of the building project and the sill can indicate a location at which the core should be fixed to the foundation.

At step 2204, the builder can install at least one pre-fabricated wall section in the building project. The pre-fabricated wall section can include a resource connection for delivering a resource to a predetermined location in the building project. The pre-fabricated wall section can be a resource node such as those example resource nodes described above. The wall section can be installed using any suitable fasteners and can be located using a unique identifier, marking or label that is fixed to the wall section during the pre-fabrication of the wall section.

At step 2206, the builder can connect at least one public resource to the pre-fabricated core. Any desired public resource can be connected such as water, sewer, gas, electricity, cable, internet or the like. The at least one public resource can be connected to the pre-fabricated core by connecting the public resource using one or more of the connection points supplied on the pre-fabricated core. The connection points can be positioned on an external side of the pre-fabricated core making all or many of the resource connections simplified and readily accessible to the user.

At step 2208, the builder can connect the resource connections that may be included on the wall sections or resource nodes to the pre-fabricated core. Because the pre-fabricated core include one or more resource distribution systems such as an electrical panel, a sewer manifold, a water supply manifold or the like, the resources nodes can be readily connected to the pre-fabricated core and thus to the public resources. In this manner, the building projected can be easily and readily connected to the public resources without complicated drawings or other tools. This is a tremendous improvement in efficiency over traditional construction methods.

The example methods and apparatuses described herein may be at least partially embodied in the form of computer-implemented processes and apparatus for practicing those processes and/or the described functionality. The disclosed methods may also be at least partially embodied in the form of tangible, non-transient machine readable storage media encoded with computer program code. The media may include, for example, RAMs, ROMs, CD-ROMs, DVD-ROMs, BD-ROMs, hard disk drives, flash memories, or any other non-transient machine-readable storage medium, or any combination of these mediums, wherein, when the computer program code is loaded into and executed by a computer, the computer becomes an apparatus for practicing the method. The methods may also be at least partially embodied in the form of a computer into which computer program code is loaded and/or executed, such that, the computer becomes an apparatus for practicing the methods. When implemented on a general-purpose processor, the computer program code segments configure the processor to create specific logic circuits. The methods may alternatively be at least partially embodied in a digital signal processor formed of application specific integrated circuits for performing the methods.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A centralized core and node system for use in an integrated component-based construction projects comprising:
a centralized core configured to be positioned on at least one external wall of a building project, the centralized core comprising:
a core frame to support one or more resource distribution mechanisms;
a core shell connected to the frame to at least partially enclose the one or more resource distribution mechanisms and form at least one part of the external wall of the building project; and
at least one resource node comprising:
a node frame; and
at least one resource connection point, the resource connection point comprising a node input for connection to the centralized core and a node output for distributing a resource to a desired location in the building project.

2. The centralized core and node system of claim 1, wherein the centralized core further comprises the one or more resource distribution mechanisms connected to the core frame.

3. The centralized core and node system of claim 2, wherein the one or more resource distribution mechanisms comprises an electrical distribution panel.

4. The centralized core and node system of claim 2, wherein the one or more resource distribution mechanisms comprises a forced air heating and cooling assembly.

5. The centralized core and node system of claim 2, wherein the one or more resource distribution mechanisms comprises a water distribution assembly.

6. The centralized core and node system of claim 2, wherein the one or more resource distribution mechanisms comprises a sewer assembly.

7. The centralized core and node system of claim 1, wherein the core further comprises one or more core inputs that are connected to the one or more resource distribution mechanisms, the one or more core inputs positioned externally to the shell and configured to connect an external resource to the one or more resource distribution mechanisms.

8. The centralized core and node system of claim 1, wherein the centralized core further comprises an access door mounted to the frame to allow access from an external location outside the building project.

9. The centralized core and node system of claim 1, wherein the centralized core further comprises a resource node positioned in a side of the frame other than the side that form at least one part of the external wall of the building project.

10. The centralized core and node system of claim 1, wherein the core shell further comprises a roof portion wherein the roof portion forms a part of a roof of the building project.

11. The centralized core and node system of claim 1, wherein the node frame comprises a plurality of support members forming a wall section having a predetermined size.

12. The centralized core and node system of claim 1, wherein the centralized core and the at least one resource node are pre-fabricated and delivered to a building site during different stages of the integrated component-based construction project.

13. The centralized core and node system of claim 1, wherein the node frame forms a wall section having a predetermined size and the at least one resource connection point is configured for connection to a sink to supply potable water and to remove waste water.

14. The centralized core and node system of claim 1, wherein the node frame forms a wall section having a predetermined size and the at least one resource connection point is configured to connect a sewer line to a toilet.

15. The centralized core and node system of claim 1, wherein the node frame forms a wall section having a predetermined size and the at least one resource connection point is configured for connection to a laundry appliance.

16. The centralized core and node system of claim 1, wherein the node frame forms a wall section having a predetermined size and the at least one resource connection point is configured for connection to a water supply for a refrigerator.

17. The centralized core and node system of claim 1, wherein the at least one resource node comprises a plurality of resource nodes positioned at predetermined locations in the building project.

18. A method of integrated component-based construction comprising:
fixing a pre-fabricated core to a foundation of a building project, the pre-fabricated core comprising an outer shell that forms at least one part of an external wall of the building project;
installing at least one pre-fabricated wall section in the building project, the at least one pre-fabricated wall section comprising a resource connection for delivering a resource to a predetermined location in the building project;
connecting at least one public resource to the pre-fabricated core; and
connecting the resource connection to the pre-fabricated core for delivery of the at least one public resource to the predetermined location in the building project.

19. The method of claim 18, wherein the pre-fabricated core comprises a second resource connection on a portion of the outer shell different than the at least one part of the external wall of the building project.

20. The method of claim 18, wherein a pre-fabricated component includes a marking fixed on an external surface thereof that indicates a location at which the pre-fabricated core is to be fixed to the foundation.
